(19) United States
(12) Patent Application Publication
(10) Pub. No.: US 2025/0005229 A1
(43) Pub. Date: Jan. 2, 2025

(54) OPTIMIZATION DEVICE, OPTIMIZATION METHOD, AND RECORDING MEDIUM

(71) Applicant: NEC Corporation, Minato- ku, Tokyo (JP)

(72) Inventors: Hanae Shimomura, Tokyo (JP); Riki Eto, Tokyo (JP); Dai Kubota, Tokyo (JP)

(73) Assignee: NEC Corporation, Minato- ku, Tokyo (JP)

(21) Appl. No.: 18/708,353

(22) PCT Filed: Mar. 11, 2022
(86) PCT No.: PCT/JP2022/010899

§ 371 Date: May 8, 2024

(51) Int. Cl. G06F 30/20

(52) U.S. Cl. CPC G06F 30/20

(57) ABSTRACT

An optimization device according to the present disclosure comprises: an optimization display means for displaying an optimization result that has been obtained on the basis of an objective function used in the optimization of an event; a change reception means for receiving a change in a parameter that determines a calculated value regarding feature constituting the objective function; an optimization execution means for optimizing the event on the basis of the changed parameter; and an optimization updating means for updating and displaying the optimization result.

### TECHNICAL FIELD

The present disclosure relates to an optimization device, an optimization method, and a recording medium.

### BACKGROUND ART

There are various tools for adjusting and verifying conditions when obtaining an event optimization result.

For example, PTL 1 discloses a multi-objective optimization device that performs an optimization by adjusting weighting values of a plurality of evaluation items (feature constituting an objective function) for multi-objective optimization.

### CITATION LIST

### Patent Literature

PTL 1: JP 2009-181195 A

### SUMMARY OF INVENTION

### Technical Problem

Apart from the optimization device described in PTL 1, there is a demand for a mechanism for easily adjusting a condition for optimizing an event and verifies whether an objective function used for optimization is valid.

An example of an object of the present disclosure is to provide an optimization device capable of easily performing trial and error on an objective function or a constraint condition by changing a condition used in optimizing an event.

### Solution to Problem

An optimization device according to an aspect of the present disclosure includes: an optimization display means that displays an optimization result obtained based on an objective function used in optimizing an event: a change reception means that receives a change in a parameter that determines a calculated value of feature constituting the objective function: an optimization execution means that optimizes the event based on the changed parameter; and an optimization update means that updates the optimization result and display the updated optimization result.

An optimization method according to an aspect of the present disclosure includes displaying an optimization result obtained based on an objective function used in optimizing an event: receiving a change in a parameter that determines a calculated value of feature constituting the objective function: optimizing the event based on the changed parameter; and updating the optimization result and display the updated optimization result.

A recording medium according to an aspect of the present disclosure records a program causing a computer to execute: displaying an optimization result obtained based on an objective function used in optimizing an event: receiving a change in a parameter that determines a calculated value of feature constituting the objective function: optimizing the event based on the changed parameter; and updating the optimization result and display the updated optimization result.

### Advantageous Effects of Invention

As an example of an effect according to the present disclosure, it is possible to provide an optimization device capable of easily performing trial and error on an objective function by changing a condition used in optimizing an event.

### BRIEF DESCRIPTION OF DRAWINGS

FIG. 1 is a diagram illustrating a configuration including an optimization device according to a first example embodiment.

FIG. 2 is a diagram illustrating a hardware configuration in which the optimization device according to the first example embodiment is achieved by a computer device and its peripheral device.

FIG. 3 is an example of a parameter change screen according to the first example embodiment.

FIG. 4 is another example illustrating a parameter change screen according to the first example embodiment.

FIG. 5 is a flowchart illustrating an optimization operation according to the first example embodiment.

FIG. 6 is a diagram illustrating a configuration including an optimization device according to a modification of the first example embodiment.

FIG. 7 is an example of a parameter change screen according to the modification of the first example embodiment.

FIG. 8 is an example of a parameter change screen according to a second example embodiment.

FIG. 9 is a diagram illustrating a configuration including an optimization device according to a modification of the second example embodiment.

FIG. 10 is a partial portion of a parameter change screen according to the modification of the second example embodiment.

FIG. 11 is a partial portion of a parameter change screen according to the modification of the second example embodiment.

FIG. 12 is a flowchart illustrating an optimization operation according to the modification of the second example embodiment.

### EXAMPLE EMBODIMENT

Next, example embodiments will be described in detail with reference to the drawings.

### First Example Embodiment

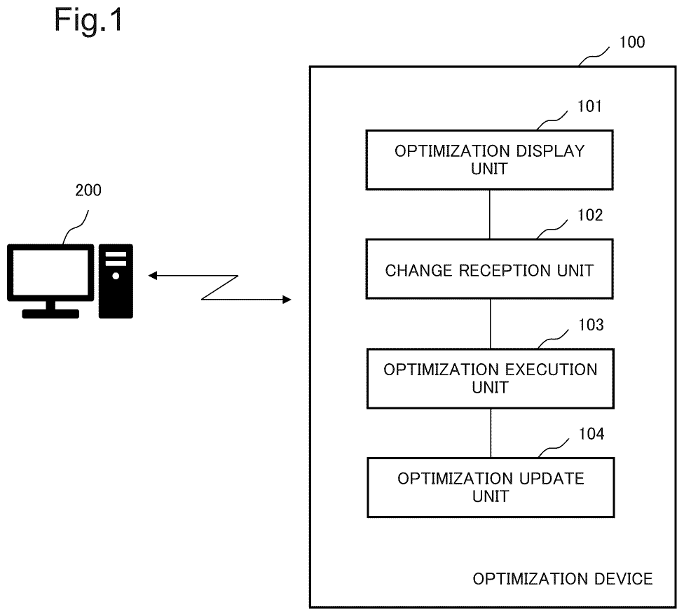

FIG. 1 is a diagram illustrating a configuration including an optimization device 100 according to a first example embodiment. Referring to FIG. 1, the optimization device 100 is communicatively connected to a terminal 200. The terminal 200 outputs information input from a user to the optimization device 100. The optimization device 100 receives a change in optimization condition input from the terminal 200 for an optimization result. In the present example embodiment, an objective function used for optimization is stored in, for example, a storage device 505. Every time the objective function is updated, the updated objective function is stored in the storage device 505.

As illustrated in FIG. 1, the optimization device 100 includes an optimization display unit 101, a change reception unit 102, an optimization execution unit 103, and an optimization update unit 104. Next, a configuration of the optimization device 100 according to the first example embodiment will be described in detail.

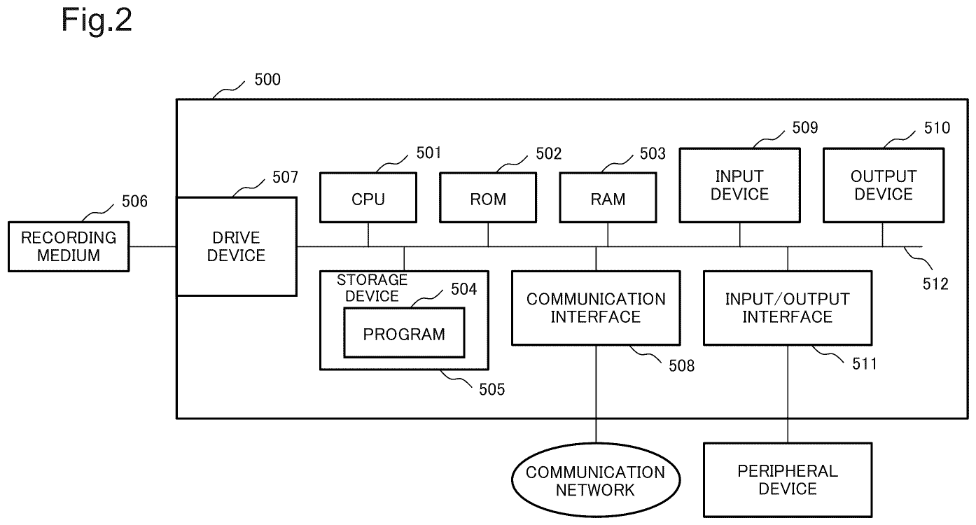

FIG. 2 is a diagram illustrating an example of a hardware configuration in which the optimization device 100 according to the first example embodiment of the present disclosure is achieved by a computer device 500 including a processor. As illustrated in FIG. 2, the optimization device 100 includes a central processing unit (CPU) 501, memories such as a read only memory (ROM) 502 and a random access memory (RAM) 503, a storage device 505 such as a hard disk that stores a program 504, a communication interface 508 for network connection, and an input/output interface 511 that inputs and outputs data. In the first example embodiment, the optimization device 100 receives parameter information input to the terminal 200 through the communication interface 508.

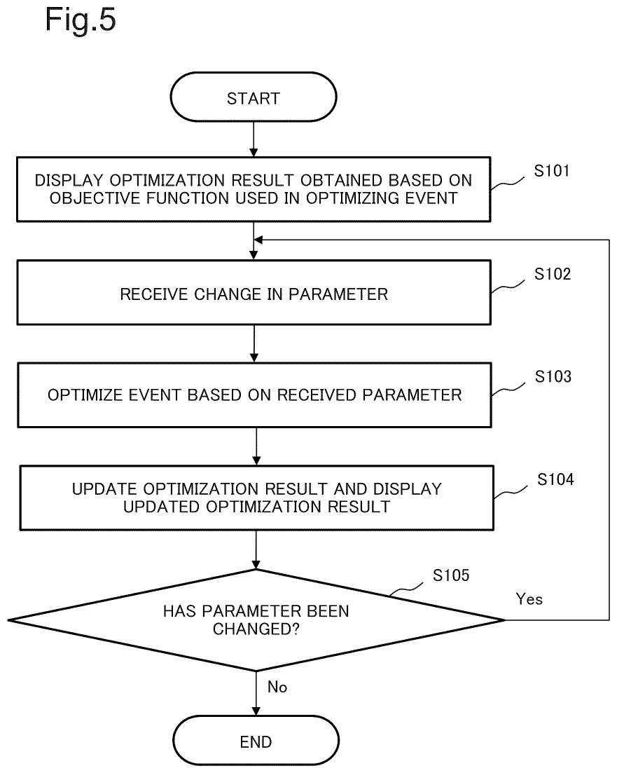

The CPU 501 operates an operating system to control the entire optimization device 100 according to the first example embodiment of the present invention. In addition, the CPU 501 reads a program or data from a recording medium 506 attached to, for example, a drive device 507 to a memory. In addition, the CPU 501 functions as the optimization display unit 101, the change reception unit 102, the optimization execution unit 103, the optimization update unit 104, or some of them in the first example embodiment, and executes a process or a command of a flowchart illustrated in FIG. 5 to be described below based on the program.

The recording medium 506 is, for example, an optical disk, a flexible disk, a magneto-optical disk, an external hard disk, a semiconductor memory, or the like. A part of the recording medium as a storage device is a non-volatile storage device, and records a program therein. In addition, a program may be downloaded from an external computer connected to a communication network although not illustrated.

The input device 509 is achieved by, for example, a mouse, a keyboard, a built-in key button, or the like, and is used for an input operation. The input device 509 is not limited to the mouse, the keyboard, or the built-in key button, and may be, for example, a touch panel. The output device 510 is achieved by, for example, a display, and is used to confirm an output.

As described above, the first example embodiment illustrated in FIG. 1 is achieved by the computer hardware illustrated in FIG. 2. However, the means for achieving each of the units included in the optimization device 100 of FIG. 1 is not limited to the configuration described above. In addition, the optimization device 100 may be achieved by one physically combined device, or may be achieved by two or more physically separated devices by connecting the plurality of devices to each other in a wired or wireless manner. For example, the input device 509 and the output device 510 may be connected to the computer device 500 via a network. Furthermore, the optimization device 100 according to the first example embodiment illustrated in FIG. 1 can also be configured by cloud computing or the like.

The optimization display unit 101 displays an optimization result obtained based on an objective function used for optimizing an event. In the present example embodiment, for example, an objective function calculated based on a historical decision data of the user is stored in the storage device 505. The optimization display unit 101 displays an optimization result obtained by inputting a value of a variable to the objective function. The optimization target is a quantity of products to be ordered by an employee at a store in the present example embodiment, but is not limited thereto. For example, the optimization target is an event that can reflect a result of decision making performed by the user in the past.

The change reception unit 102 receives a change in a parameter that determines a calculated value of feature constituting the objective function. The change reception unit 102 receives a parameter input to the terminal 200 and outputs the parameter to the optimization execution unit 103.

Here, the objective function, the feature, and the parameter will be described. The objective function according to the present example embodiment is a reference for optimizing a target, and is expressed by a weighted linear sum of feature. In addition, the objective function is calculated by a known machine learning method. The parameter is a variable that determines a calculated value of feature constituting the objective function, and examples of the parameter include a variable of state data included in the historical decision data, a weighting coefficient, and the like. In the present example embodiment, as shown in the following Formula (1), a value of the objective function is expressed as Z that maximizes f(x).

$$\begin{matrix}[ Formula 1 ] & \\ Z = max f ( x ) = {λ}_{1} {x}_{1} + {λ}_{2} {x}_{2} + {λ}_{3} {x}_{3} + … + {λ}_{n} {x}_{m} & ( 1 )\end{matrix}$$

In Formula (1), λₙ is a weighting coefficient, and xₘ is feature. In the present example embodiment, the objective function is an objective function for minimizing disposal loss and stockout loss. In addition, n=m=2 in Formula (1), feature x₁ is how small the disposal loss is, and feature x₂ is how small the stockout loss is. The parameters in the present example embodiment are a minimum value of a predicted sales quantity, a maximum value of a predicted sales quantity, an inventory quantity, a purchase price, and a sales price. These parameters are used to determine the feature x₁ and the feature x₂. The disposal loss (feature x₁) is determined according to (inventory quantity-minimum value of predicted sales quantity)×purchase price, and the stockout loss (feature x₂) is determined according to sales price×(maximum value of predicted sales quantity-inventory quantity).

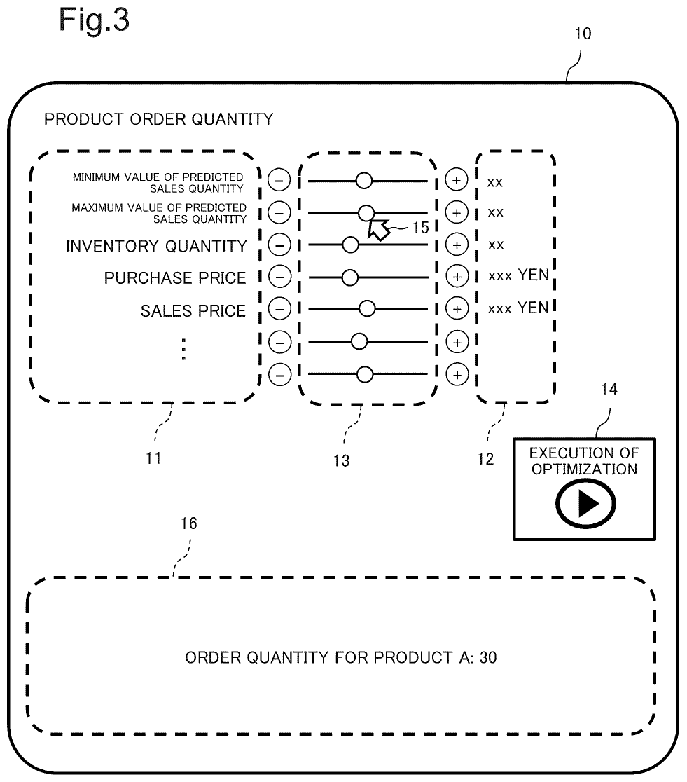

Next, an example of a parameter change operation performed by the user will be described. FIG. 3 is an example of a parameter change screen according to the first example embodiment. As illustrated in FIG. 3, a parameter change screen 10 includes a first display area 11 where a plurality of parameters are displayed. In addition, the parameter change screen 10 includes a second display area 12 where respective values of the parameters are displayed. In addition, the parameter change screen 10 includes a third display area 13 where an adjustment bar such as a seek bar for receiving a change in a parameter. In addition, the parameter change screen 10 includes a button image 14 for the user to instruct the optimization device 100 to change the parameter and a result display area 16 where an optimization result is shown. In the present example embodiment, the optimization target displayed in the result display area 16 is a product order quantity.

When the user desires to change a value of a certain parameter, the user changes the value of the parameter by moving a position of an indicator 15 in the third display area 13 of the parameter change screen 10 by a drag operation using the input device 509 such as a numeric keypad or a mouse.

In the present example embodiment, when the user moves the indicator 15 to the left side, the value of each parameter decreases (down). In addition, when the user moves the indicator 15 to the right side, the value of the parameter increases (up).

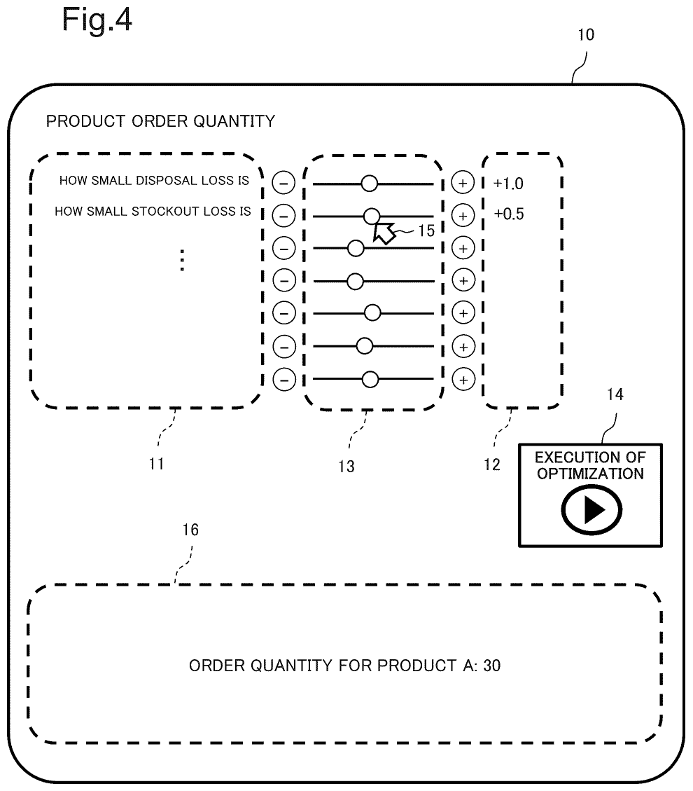

FIG. 4 is another example illustrating a parameter change screen according to the first example embodiment. On the screen of FIG. 4, the weighting coefficient M of how small the disposal loss as the feature x₁ and the weighting coefficient 22 of how small the stockout loss as the feature x₂ are changed in the range of, for example, +0.1 to +1.0. However, the range in which the weighting coefficients can be changed is not limited thereto.

The optimization execution unit 103 is a means for executing an optimization of an event based on a received parameter. When detecting that the user presses the change start button image 14, the optimization execution unit 103 executes an optimization in which the changed value of the parameter is reflected. That is, in the example of FIG. 3, the optimization execution unit 103 calculates feature from the value of the parameter and updates the objective function based on Formula (1). In the example of FIG. 4, the optimization execution unit 103 inputs the changed value of the weighting coefficient to Formula (1) and updates the objective function.

Next, the optimization execution unit 103 obtains a product order quantity, which is an optimization target, based on the updated objective function. The optimization execution unit 103 outputs the obtained optimization result to the optimization update unit 104.

The optimization update unit 104 is a means for updating the optimization result obtained by the optimization execution unit 103 and displaying the updated optimization result. The optimization update unit 104 updates the optimization result in the result display area 16 and displays the updated optimization result on the parameter change screen 10. The optimization update unit 104 may display a difference (change point) of the updated optimization result in an emphasized manner as well as the updated optimization result.

An operation of the optimization device 100 configured as described above will be described with reference to the flowchart of FIG. 5.

FIG. 5 is a flowchart illustrating an outline of an operation of the optimization device 100 according to the first example embodiment. Note that the process according to this flowchart may be executed based on the program control by the processor described above.

As illustrated in FIG. 5, first, the optimization display unit 101 displays an optimization result obtained based on an objective function used in optimizing an event (step S101). Next, the change reception unit 102 receives a change in a parameter that determines a value of feature (step S102). Next, the optimization execution unit 103 optimizes the event based on the received parameter (step S103). Finally, the optimization update unit 104 updates the optimization result obtained by the optimization execution unit 103 and displays the updated optimization result (step S104). The optimization device 100 repeats the flow of steps S102 to S104 each time a change in a parameter is detected (step S105). Then, the optimization device 100 ends the optimization operation.

In the optimization device 100, the optimization execution unit 103 executes an optimization of an event based on a parameter changed by the user. By doing so, it is possible to easily perform trial and error on the objective function by changing a condition used in optimizing an event.

Further, in the first example embodiment, the change reception unit 102 receives a change in a parameter that determines a value of feature. In this case, it is possible to easily perform trial and error on the objective function by changing a condition that determines a value of feature. In particular, the change reception unit 102 receives a change in a weighting coefficient of feature as a parameter. As a result, in a case where there is feature that the user wants to emphasize, it is possible to output an optimization result reflecting the emphasized feature.

### Modification of First Example Embodiment

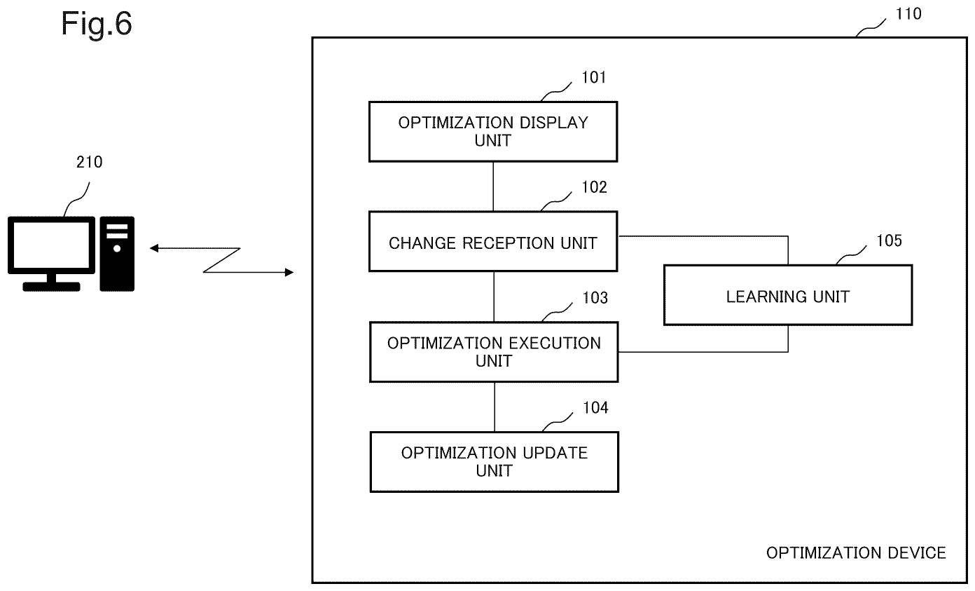

Next, a modification of the first example embodiment will be described with reference to the drawings. Hereinafter, description overlapping with what has been described above will be omitted unless the omission obscures the description of the present example embodiment. FIG. 6 illustrates a configuration including an optimization device 110 according to a modification of the first example embodiment. As illustrated in FIG. 6, the optimization device 110 according to the modification of the first example embodiment is different in that a learning unit 105 is provided in addition to the configuration of the first example embodiment. In addition, in the first example embodiment, the change reception unit 102 receives a change in a parameter, and the optimization execution unit 103 executes an optimization based on the changed parameter. On the other hand, in the modification of the first example embodiment, the change reception unit 102 receives a change in an optimization result in addition to the change of the parameter.

The change in the optimization result is a change in a product order quantity, which is an optimization result in the present example embodiment. When the change reception unit 102 receives a change of an optimization result, the learning unit 105 fine-tunes the objective function with the received optimization result being included as a historical decision data. The learning unit 105 stores the fine-tuned objective function in the storage device 505.

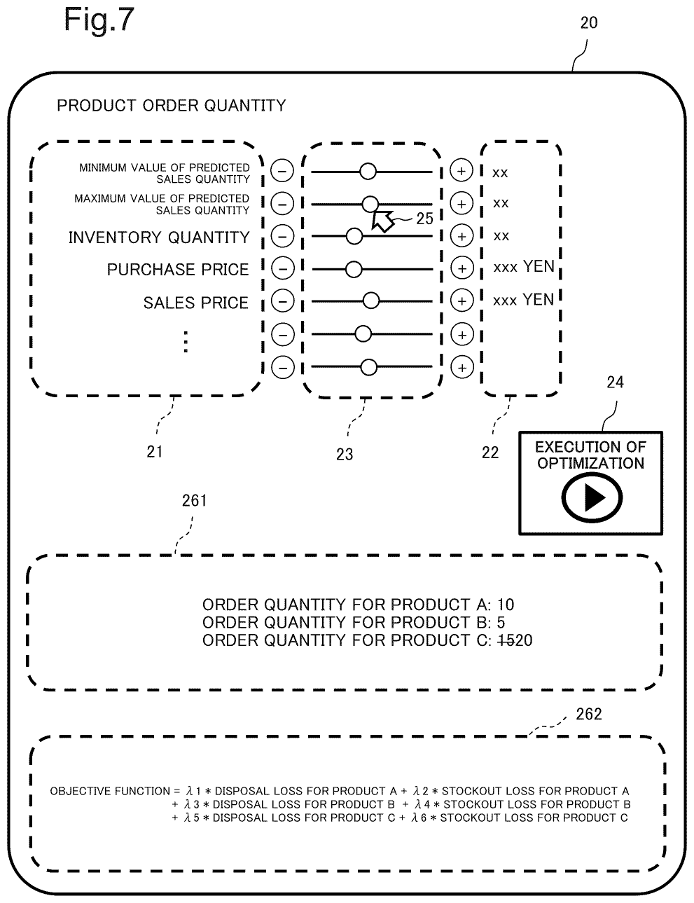

FIG. 7 is an example of a parameter change screen according to the modification of the first example embodiment. As illustrated in FIG. 7, a parameter change screen 20 includes a result display area 261 where an optimization result is shown and an objective function display area 262 where an objective function used in calculating the optimization result is shown. Numerical values of the weighting coefficients are shown in λ₁ to λ₆ of the objective function shown in the objective function display area 262. In this case, the change reception unit 102 can receive a change in a product order quantity shown in the result display area 261 on the screen. In the example of FIG. 7, the order quantity for product C is changed from 15 to 20. In this case, the value of the weighting coefficient λ₆ of the objective function shown in the objective function display area 262 is updated so as to emphasize the smallness of the stockout loss. In addition, the change reception unit 102 may also receive a change in a weighting coefficient (λ₁ to λ₆) of the objective function shown in the objective function display area 262 on the screen.

In the modification of the first example embodiment, the change reception unit 102 receives a change in an optimization result in addition to the change of the parameter. As a result, the user can execute an optimization while performing trial and error on the optimization result.

### Second Example Embodiment

Next, a second example embodiment of the present disclosure will be described in detail with reference to the drawings. The second example embodiment is different from the first example embodiment in an optimization target, while having the same configuration as the first example embodiment. Hereinafter, description overlapping with what has been described above will be omitted unless the omission obscures the description of the present example embodiment. The functions in the present example embodiment can be achieved not only by hardware similarly to the computer device in the first example embodiment as illustrated in FIG. 2 but also by a computer device based on program control or software. In the present example embodiment, shift scheduling is used as an optimization target. The objective function in the present example embodiment is an objective function that maximizes an evaluation of a shift.

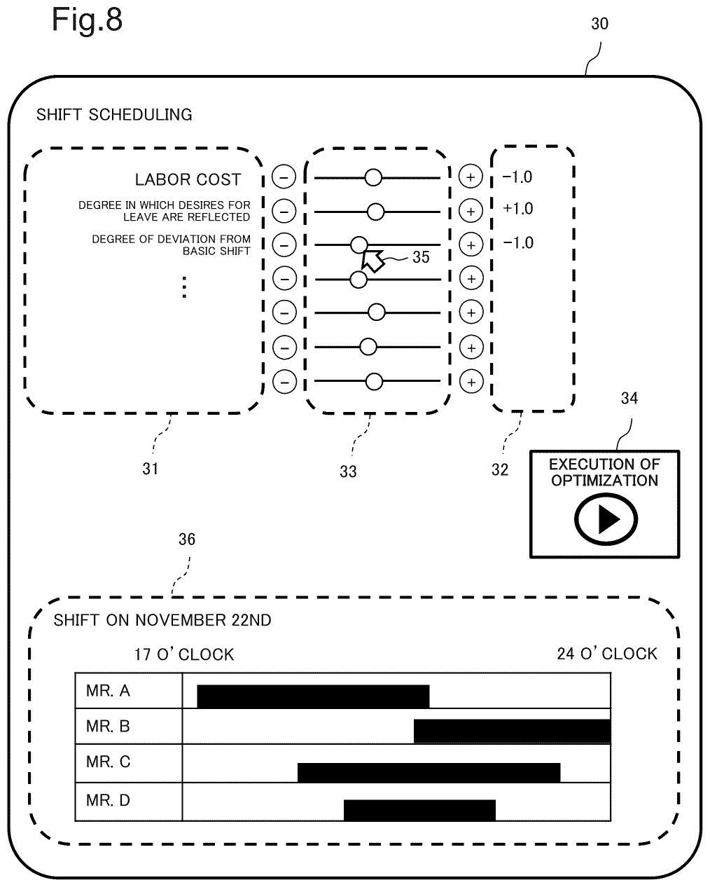

FIG. 8 is an example of a parameter change screen 30 according to the second example embodiment. As illustrated in FIG. 8, feature of the objective function is displayed in a first display area 31. Weighting coefficient of the feature of the objective function are displayed in a second display area 32. Adjustment bars such as seek bars for receiving changes in the respective parameters are displayed in a third display area 33. In addition, the parameter change screen 30 includes a button image 34 for the user to instruct the optimization device 120 to change the parameter and a result display area 36 where an optimization result is shown. The feature of the objective function includes a labor cost, a degree in which desires for leave are reflected, and a degree of deviation from the basic shift. The labor cost is expressed as a negative numerical value, and the larger the labor cost, the smaller the objective function. The degree in which the desires for leave are reflected is an index indicating whether desires of employees for leave are reflected, and is expressed as a positive numerical value, and the higher the numerical value, the larger the objective function. The degree of deviation from the basic shift is expressed as a negative numerical value, and the larger the numerical value, the smaller the objective function. In the result display area 36, a shift schedule is displayed as an optimization result.

In the present example embodiment, a parameter to be changed is a weighting coefficient of feature of the objective function. As illustrated in FIG. 8, the change reception unit 102 receives the change in the weighting coefficient of the feature of the objective function in the range of, for example, −1.0 to +1.0.

When detecting that the user presses the change start button image 34, the optimization execution unit 103 executes an optimization in which the weighting coefficient changed by the user moving a position of an indicator 35 on the parameter change screen 30 is reflected. That is, the optimization execution unit 103 updates the objective function using Formula (1).

Next, the optimization execution unit 103 obtains a result of scheduling, which is an optimization target, based on the updated objective function. Then, the optimization update unit 104 updates the optimization result in the result display area 36 and displays the updated optimization result on the parameter change screen 30.

### Modified Example of Second Example Embodiment

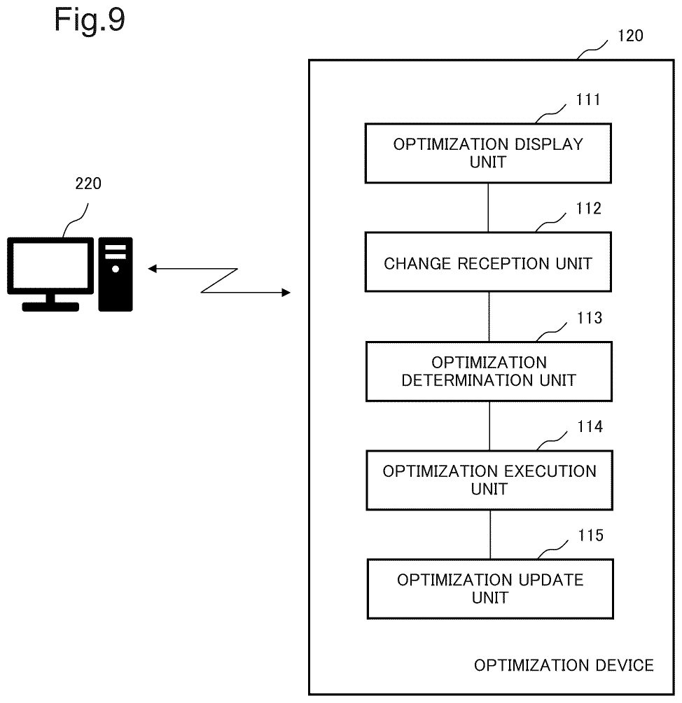

Next, a modification of the second example embodiment will be described with reference to the drawings. Hereinafter, description overlapping with what has been described above will be omitted unless the omission obscures the description of the present example embodiment. FIG. 9 is a diagram illustrating a configuration including an optimization device 120 according to a modification of the second example embodiment of the present disclosure. With reference to FIG. 9, the optimization device 120 according to the modification of the second example embodiment will be described focusing on a difference from the optimization device 100 according to the first example embodiment.

The optimization device 120 according to the modification of the second example embodiment includes an optimization display unit 111, a change reception unit 112, an optimization determination unit 113, an optimization execution unit 114, and an optimization update unit 115. Since the configuration of the optimization display unit 111 and the change reception unit 112 is similar to the configuration of the optimization display unit 101 and the change reception unit 102 in the first example embodiment, the description thereof is omitted.

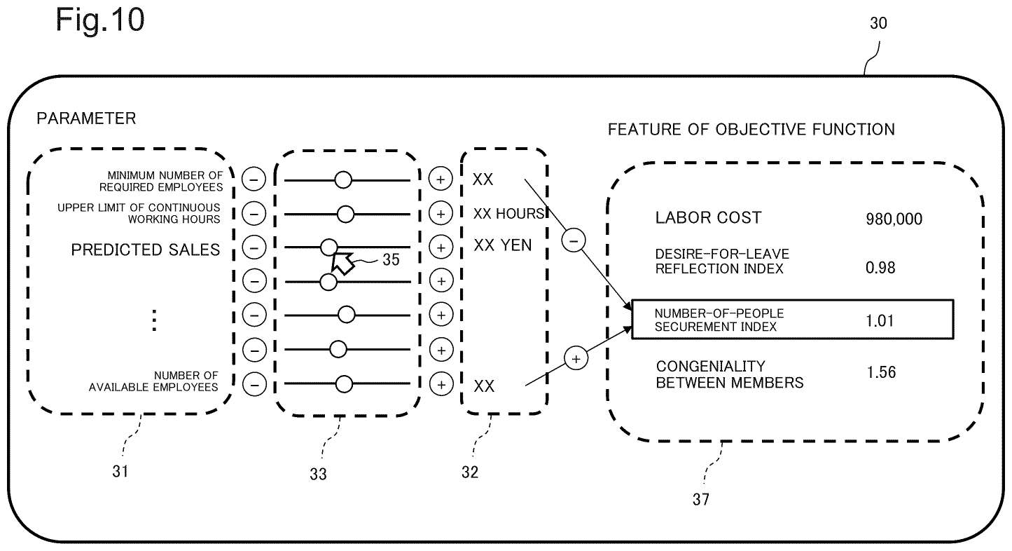

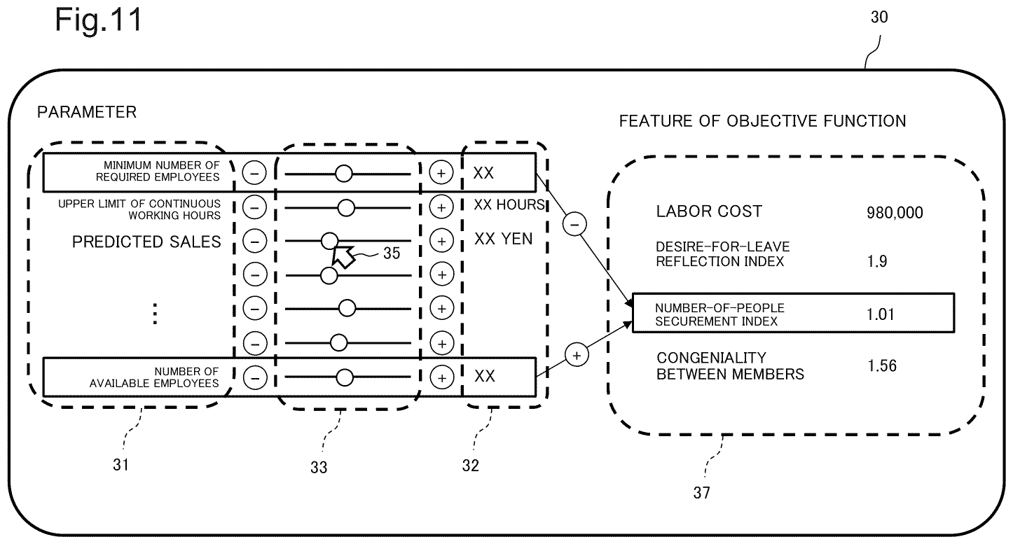

Each of FIGS. 10 and 11 is a partial portion of a parameter change screen according to the modification of the second example embodiment. As illustrated in FIG. 10, parameters that determine calculated values of feature of the objective function are displayed in a first display area 31. Values of the parameters are displayed in a second display area 32. In the present example embodiment, the calculated values of the feature as an optimization result are displayed in a fourth display area 37 by the optimization display unit 111. The calculated values of the feature are indexes for confirming the effectiveness of the optimization. In addition, as illustrated in FIG. 10, the optimization display unit 111 may display a relationship between a parameter and feature on the parameter change screen 30. In the example of FIG. 10, when the minimum number of required employees is reduced (“−”), it is in an increasing relationship with a number-of-people securement index. On the other hand, when the number of available employees is increased (“+”), it is in an increasing relationship with the number-of-people securement index. In this case, for example, when the minimum number of required people is larger than a predetermined number or when the number of available employees is smaller than the predetermined number, the minimum number of required people or the number of available employees does not satisfy the calculated value of the number-of-people securement index.

The optimization determination unit 113 is a means for determining whether the received parameter with which the calculated value of the feature can be taken. When a parameter is input from the change reception unit 112, the optimization determination unit 113 determines whether the parameter has a value with which feature displayed in the fourth display area 37 of the parameter change screen 30 can be taken based on the relational expression between the parameter and the feature.

When the calculated value of the feature is a value that can be taken based on the received parameter, the optimization determination unit 113 outputs a signal indicating the same to the optimization execution unit 114. On the other hand, when the calculated value of the feature is not a value that can be taken, the optimization determination unit 113 controls, for example, the terminal 220 to display the calculated value of the feature that cannot be taken in an emphasized manner as illustrated in FIG. 10. Furthermore, when the calculated value of the feature is not a value that can be taken, the optimization determination unit 113 controls the terminal 220 to display a parameter that affects the feature in an emphasized manner as illustrated in FIG. 11.

When a signal indicating that the calculated value of the feature is a value that can be taken is input from the optimization determination unit 113, the optimization execution unit 114 updates the objective function based on the changed feature and obtains an optimization result.

The optimization update unit 115 updates the optimization result obtained by the optimization execution unit 114 and displays the updated optimization result. As illustrated in FIG. 11, the optimization update unit 115 may perform display in such a way that the relationship between the parameter for which the change has been received and the feature affected by the changed parameter can be grasped.

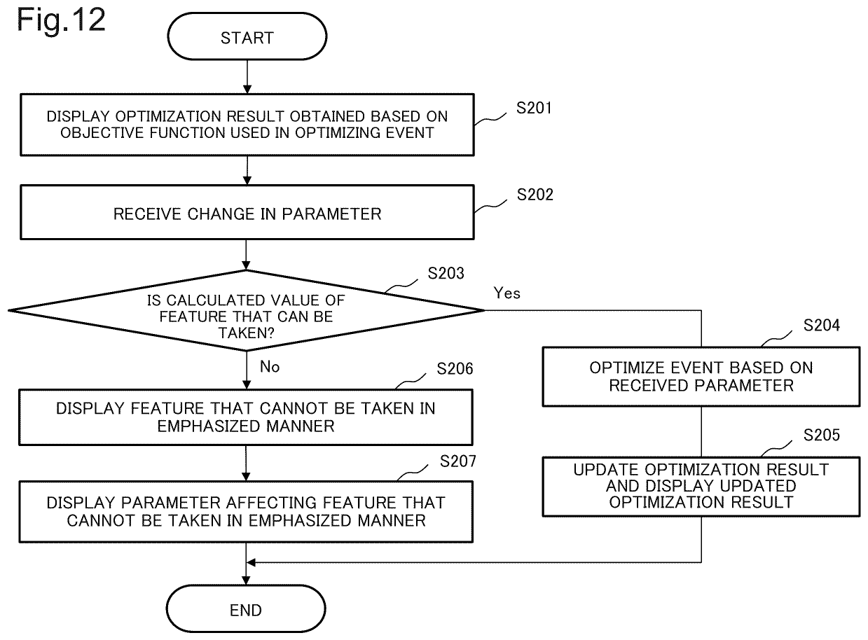

An operation of the optimization device 120 configured as described above will be described with reference to the flowchart of FIG. 12.

FIG. 12 is a flowchart illustrating an outline of an operation of the optimization device 120 according to the second example embodiment. Note that the process according to this flowchart may be executed based on the program control by the processor described above.

As illustrated in FIG. 12, first, the optimization display unit 111 displays an optimization result obtained based on an objective function used in optimizing an event (step S201). Next, the change reception unit 112 receives a change in a parameter that determines feature (step S202). Next, the optimization determination unit 113 determines whether a calculated value of feature can be taken with the changed parameter (step S203). When the optimization determination unit 113 determines that the calculated value of the feature can be taken with the changed parameter (step S203: Yes), the optimization execution unit 114 optimizes the event based on the received parameter (step S204). Next, the optimization update unit 115 updates the optimization result obtained by the optimization execution unit 114 and displays the updated optimization result (step S205). On the other hand, when the optimization determination unit 113 determines that the calculated value of the feature cannot be taken with the changed parameter (step S203: No), the optimization determination unit 113 causes the feature that cannot be taken in an emphasized manner (step S206). Furthermore, the optimization determination unit 113 causes the parameter affecting the feature that cannot be taken in an emphasized manner (step S207). Then, the optimization device 120 ends the optimization operation.

In the modification of the second example embodiment of the present disclosure, when a calculated value of feature cannot be taken with a changed parameter, the optimization determination unit 113 displays the feature and the parameter in an emphasized manner. As a result, the user can change the parameter that cannot be achieved and the feature that affects the parameter, and perform an optimization again.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

For example, although a plurality of operations are described in order in the form of a flowchart, the order in which the operations are described does not limit an order in which the plurality of operations are executed. Therefore, when each example embodiment is implemented, the order in which the plurality of operations are executed can be changed if the content is not affected by the change. For example, although the optimization determination unit 113 performs control to display feature that cannot be taken in an emphasized manner (step S206), and then performs control to display a parameter that affects the feature in an emphasized manner (step S207) in the modification of the second example embodiment, the order is not limited thereto. The optimization determination unit 113 may perform control to display the parameter in an emphasized manner and then perform control to display the feature in an emphasized manner. Furthermore, the optimization determination unit 113 may perform control to display either the feature or the parameter in an emphasized manner.

### REFERENCE SIGNS LIST

100, 110, 120 Optimization device
101, 111 Optimization display unit
102, 112 Change reception unit
103, 114 Optimization execution unit
104, 115 Optimization update unit
105 Learning unit
113 Optimization determination unit

What is claimed is:

1. An optimization device comprising:
a memory storing instructions; and
at least one processor configured to execute the instructions to:
display an optimization result obtained based on an objective function used in optimizing an event;
receive a change in a parameter that determines a calculated value of feature constituting the objective function;
optimize the event based on the changed parameter; and
update the optimization result and display the updated optimization result.

2. The optimization device according to claim 1, wherein the parameter is a parameter that defines a weighting coefficient of the feature.

3. The optimization device according to claim 1, wherein the at least one processor is further configured to execute the instructions to:
receive the change in the parameter by changing a position of an indicator of an adjustment bar displayed on a screen.

4. The optimization device according to claim 1, wherein the at least one processor is further configured to execute the instructions to: display a relationship between the received parameter and the calculated value of the feature.

5. The optimization device according to claim 1, wherein the at least one processor is further configured to execute the instructions to:
determine whether the received parameter has a value with which the calculated value of the feature can be taken.

6. The optimization device according to claim 5, wherein the at least one processor is further configured to execute the instructions to:
display the calculated value of the feature in an emphasized manner when the calculated value of the feature is a value that cannot be taken.

7. The optimization device according to claim 5, wherein the at least one processor is further configured to execute the instructions to:
display the parameter affecting the feature in an emphasized manner when the calculated value of the feature is a value that cannot be taken.

8. The optimization device according to claim 1, wherein the at least one processor is further configured to execute the instructions to:
receive a change in the optimization result of the event, and
fine-tune an objective function with the received optimization result being included as a historical decision data.

9. An optimization method comprising:
displaying an optimization result obtained based on an objective function used in optimizing an event;
receiving a change in a parameter that determines a calculated value of feature constituting the objective function;
optimizing the event based on the changed parameter; and
updating the optimization result and display the updated optimization result.

10. A non-transitory computer readable recording medium recording a program for causing a computer to execute:
displaying an optimization result obtained based on an objective function used in optimizing an event;
receiving a change in a parameter that determines a calculated value of feature constituting the objective function;
optimizing the event based on the changed parameter; and
updating the optimization result and display the updated optimization result.
